(19) United States
(12) Patent Application Publication
(10) Pub. No.: US 2014/0209380 A1
(43) Pub. Date: Jul. 31, 2014

(54) ASSEMBLING STRUCTURE FOR FLEXIBLE FLAT CABLE OF TOUCH PANEL

(71) Applicant: Kai-Ti YANG, Taoyuan (TW)

(72) Inventor: Kai-Ti YANG, Taoyuan (TW)

(73) Assignee: Young Fast Optoelectronics Co., Ltd.

(21) Appl. No.: 13/753,520

(22) Filed: Jan. 30, 2013

(51) Int. Cl. H05K 1/11

(52) U.S. Cl. CPC H05K 1/118
USPC 174/99 R

(57) ABSTRACT

The invention includes a touch film, a transparent substrate, a covering layer and an FFC. The touch film is transparent and flexible and has an upper conductive film on a bottom side thereof. The transparent substrate is adhered and superposed under the touch film and has a lower conductive film facing the upper conductive film. Peripheries of the upper and lower conductive films are provided with silver conductive paths, and ends of the silver conductive paths are formed with a first set of signal contacts. The covering layer is adhered on the touch film. The FFC has a second set of signal contacts corresponding to the first set of signal contacts. The touch film is formed with a recess over the first and second sets of signal contacts, and a width of the recess is slightly greater than that of the FFC.

### BACKGROUND OF THE INVENTION

1. Technical Field

The invention relates to touchscreen panels, particularly to touch panels used in compact electronic devices.

2. Related Art

Touch panels have been extensively applied in general consumer electronic products as an interactive human-machine interface.

A typical resistive touch panel includes two sheets of resistive films with an interval. Usually, the upper one is placed on a flexible transparent film and the lower one is placed on a rigid glass substrate. There are spacer protrusions between the two films. Peripheries of the two films are adhered with an adhesive. Peripheries of the two resistive films are further provided with a circuit area composed of silver conductive paths for transmitting signals from the resistive films. An end of the circuit area is formed with signal contacts for connecting a flexible flat cable (FFC). Thus, signals from the resistive films can be transmitted to a controller through the FFC.

Generally speaking, the connector of the FFC, which connects to the signal contacts of the circuit area is nipped between the transparent film and the glass substrate. However, because the FFC has a certain thickness and the thickness is much greater than the gap between the transparent film and the glass substrate, this will cause the panel to protrude. Such protrusion results in not only exterior unevenness but also difficulties in assembling. Especially, this kind of panel cannot be applied in thin products with fully planar appearance (for example, iPhone® and iPod®). Additionally, when using the panel, the protrusion tends to bear undue pressure, thus the electric connection is easy to be damaged. Furthermore, The sealing effect in the portion around the protrusion must be reduced to affect the performance of water-resistance and dust-resistance. Finally, when assembling, the connector of the FFC is hard to be set in a correct position.

### SUMMARY OF THE INVENTION

An object of the invention is to provide an improved assembling structure for flexible flat cable of touch panel, which can enhance the assembling accuracy of the flexible flat cable of the touch panel and can guarantee flatness and smoothness of appearance of products using the panel.

To accomplish the above object, the invention includes a touch film, a transparent substrate, a covering layer and an FFC. The touch film is transparent and flexible and has an upper conductive film on a bottom side thereof. The transparent substrate is adhered and superposed under the touch film and has a lower conductive film facing the upper conductive film. Peripheries of the upper and lower conductive films are provided with silver conductive paths, and ends of the silver conductive paths are formed with a first set of signal contacts. The covering layer is adhered on the touch film. The FFC has a second set of signal contacts corresponding to the first set of signal contacts. The touch film is formed with a recess over the first and second sets of signal contacts, and a width of the recess is slightly greater than that of the FFC.

### BRIEF DESCRIPTION OF THE DRAWINGS

FIG. 1 is an exploded view of the invention; and

FIG. 2 is a cross-sectional view of the invention.

### DETAILED DESCRIPTION OF THE INVENTION

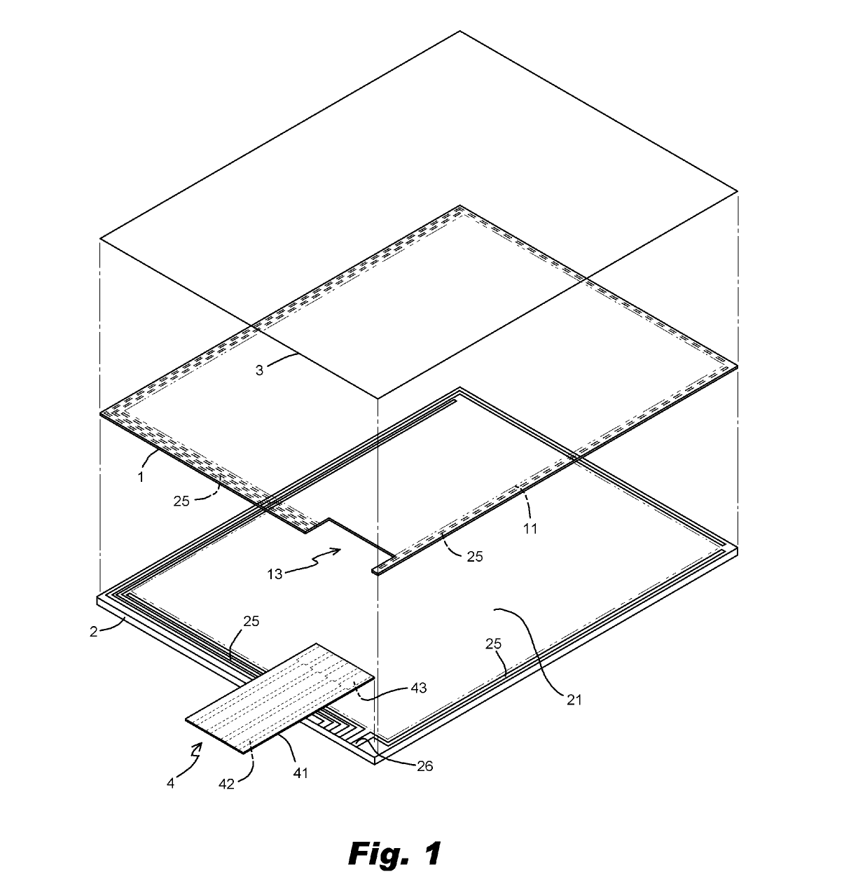

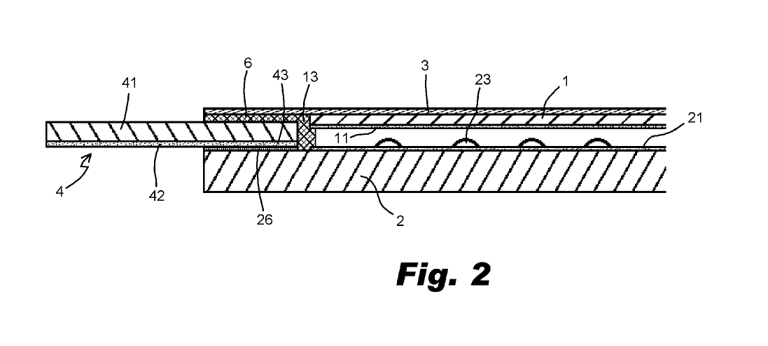

Please refer to FIGS. 1 and 2. The touch panel of the invention includes a touch film 1, a transparent substrate 2, a covering layer 3 and a flexible flat cable (FFC) 4. The touch film 1 is transparent and flexible and has an upper conductive film 11 on the bottom side thereof. The transparent substrate 2 is adhered and superposed under the touch film 1 and has a lower conductive film 21 facing the upper conductive film 1. A plurality of spacer protrusions 23 are disposed between the upper and lower conductive films 11, 21. Peripheries of the upper and lower conductive films 11, 21 are separately provided with silver conductive paths 25. Ends of the silver conductive paths 25 are formed with a first set of signal contacts 26. The touch film 1 is formed with a recess 13 over the first and second sets of signal contacts 26. A width of the recess 13 is slightly greater than that of the FFC 4. The covering layer 3 is adhered on the outside of the touch film 1. A working surface (outer surface) of the covering layer 3 is provided with a hard coating for purposes of anti-scratch and anti-dirt, such as a layer formed by high hardness UV cured paint. The FFC 4 is composed of a sheet of flexible tape 41 and wires 42 disposed thereon and has a second set of signal contacts 43 corresponding to the first set of signal contacts 26. As a result, the first and second sets of signal contacts 26, 43 can be received in the recess 13. Preferably, the recess 13 is of a rectangular shape. The FFC 4 is out of contact with the touch film 1 and the covering layer 3, so the touch film 1 and the covering layer 3 can keep smooth and flat.

When assembling, the second set of signal contacts 43 is placed over and in contact with the first set of signal contacts 26 first, in which an anisotropic conductive film (ACF) is applied therebetween. Then, use a hot pressing tool (not shown) to heat up the ACF and make the two sets of signal contacts 26, 43 adhered to each other. As a result, an effect of vertical conduction and horizontal insulation is obtained. Meanwhile, the FFC 3 is firmly secured on the touch panel. Next, fill silicone material into the recess 13 to seal up the two sets of signal contacts 26, 43. Finally, the covering layer 3 is spread on the touch panel to cloak the recess 13. Accordingly, signals from the upper and lower conductive films 11, 21 are transmitted to a processor (not shown) through the silver conductive paths 25 and FFC 4. This can enhance the assembling accuracy of the flexible flat cable of the touch panel and can guarantee flatness and smoothness of appearance of products using the panel.

While the forgoing is directed to a preferred embodiment of the present invention, other and further embodiments of the invention may be devised without departing from the basic scope thereof, for example, the first set of signal contacts of the silver conductive paths are arranged on the touch film and the recess is arranged in the transparent substrate. As such, the appropriate scope of the invention is to be determined according to the claims.

What is claimed is:

1. An assembling structure for a touch panel, comprising:
a touch film, being transparent and flexible, and having an upper conductive film on a bottom side thereof;
a transparent substrate, adhered and superposed under the touch film, and having a lower conductive film facing the upper conductive film, wherein a plurality of spacer protrusions are disposed between the upper and lower conductive films, peripheries of the upper conductive film and the lower conductive film are separately provided with silver conductive paths, and ends of the silver conductive paths are formed with a first set of signal contacts;
a covering layer, adhered on the touch film; and
a flexible flat cable (FFC), having a second set of signal contacts corresponding to the first set of signal contacts;
wherein the touch film is formed with a recess over the first and second sets of signal contacts, and a width of the recess is slightly greater than that of the FFC so that the first and second sets of signal contacts are received in the recess.

2. The assembling structure of claim 1, wherein the recess is of a rectangular shape.

3. The assembling structure of claim 1, wherein the FFC is out of contact with the touch film and the covering layer.
